(19) United States
(12) Patent Application Publication
(10) Pub. No.: US 2024/0268156 A1
(43) Pub. Date: Aug. 8, 2024

(54) DISPLAY APPARATUS AND METHOD OF MANUFACTURING THE SAME

(71) Applicant: Samsung Display Co., Ltd., Yongin-si (KR)

(72) Inventors: Cheho Lee, Yongin-si (KR); Soyeon Jeong, Yongin-si (KR); Wonje Jo, Yongin-si (KR); Shogo Nishizaki, Yongin-si (KR); Jaehyun Kim, Yongin-si (KR)

(73) Assignee: Samsung Display Co., Ltd., Yongin-si (KR)

(21) Appl. No.: 18/507,280

(22) Filed: Nov. 13, 2023

(30) Foreign Application Priority Data
Feb. 8, 2023 (KR) 10-2023-0016896

(51) Int. Cl. H10K 59/122; H10K 59/12; H10K 59/35

(52) U.S. Cl. CPC H10K 59/122; H10K 59/1201; H10K 59/353

(57) ABSTRACT

A display apparatus includes pixel electrodes disposed on a substrate, each of the pixel electrodes spaced apart from each other, a pixel-defining layer covering edges of each of the pixel electrodes, metal layers disposed on the pixel-defining layer, having an island shape, disposed corresponding to spaces between the pixel electrodes, and spaced apart from each other, and an opposite electrode covering the metal layers.

### CROSS-REFERENCE TO RELATED APPLICATION(S)

This application claims priority to and benefits of Korean Patent Application No. 10-2023-0016896 under 35 U.S.C. § 119, filed on Feb. 8, 2023, in the Korean Intellectual Property Office (KIPO), the entire contents of which are incorporated herein by reference.

### BACKGROUND

### 1. Technical Field

Embodiments relate to a display apparatus and a method of manufacturing the display apparatus.

### 2. Description of the Related Art

Recently, the usage of display apparatuses has diversified. In addition, as a thickness of a display apparatus becomes thin and lightweight, the range of usage tends to widen, and research of a display apparatus that may be used in various fields is carried out consistently.

### SUMMARY

Embodiments include a display apparatus with improved reliability, wherein a metal layer is disposed on a pixel-defining layer, and a method of manufacturing the display apparatus. However, such a technical problem is an example, and the disclosure is not limited thereto.

Additional aspects will be set forth in part in the description which follows and, in part, will be apparent from the description, or may be learned by practice of the presented embodiments of the disclosure.

According to an embodiment, a display apparatus may include pixel electrodes disposed on a substrate, each of the pixel electrodes being spaced apart from each other, a pixel-defining layer covering edges of each of the pixel electrodes, metal layers disposed on the pixel-defining layer, having an island shape, disposed corresponding to spaces between the pixel electrodes, and spaced apart from each other, and an opposite electrode covering the metal layers.

The metal layers may be arranged at constant interval.

Each of the metal layers may have a same shape in a plan view.

The display apparatus may further include first pixels, second pixels, and third pixels that emit light of different colors disposed on the substrate. The first pixels and the third pixels may be alternately arranged along a first virtual line extending in a first direction, the second pixels may be arranged along a second virtual line parallel to the first virtual line and adjacent to the first virtual line corresponding to a space between adjacent ones of the first pixels and the third pixels, the metal layers may include first metal layers and second metal layers, the first metal layers may be arranged between adjacent ones of the first pixels and the third pixels on the first virtual line, and the second metal layers may be arranged between the second pixels.

The first metal layers and the second metal layers may each be arranged at constant interval in the first direction.

An interval between the first metal layers and an interval between the second metal layers may be same.

One of the first metal layers and one of the second metal layers that are disposed most adjacent to each other may be connected to each other and integral with each other.

The pixel-defining layer may include an opening exposing at least a portion of an upper surface of each of the pixel electrodes, and the display apparatus may further include an emission layer overlapping the opening in a plan view.

The display apparatus may further include a capping layer and an inorganic encapsulation layer covering the opposite electrode.

According to an embodiment, a method of manufacturing a display apparatus may include preparing a substrate, forming pixel electrodes spaced apart from each other on the substrate, forming a pixel-defining layer covering edges of each of the pixel electrodes, forming a metal layer on the pixel-defining layer, forming a spacer on the metal layer, and removing the spacer.

The removing of the spacer may include irradiating a laser beam to the metal layer.

The removing of the spacer may include performing a stamping process.

The metal layer may include a plurality of metal layers arranged in an island shape on the pixel-defining layer, and the plurality of metal layers are spaced apart from each other.

The plurality of metal layers may have a same shape in a plan view.

The plurality of metal layers may be arranged at constant interval.

The method may further include forming first pixels, second pixels, and third pixels that emit light of different colors on the substrate. The first pixels and the third pixels may be alternately arranged along a first virtual line extending in a first direction, the second pixels may be arranged along a second virtual line parallel to the first virtual line and adjacent to the first virtual line corresponding to a space between adjacent ones of the first pixels and the third pixels, the plurality of metal layers may include first metal layers and second metal layers, the first metal layers may be arranged between adjacent ones of the first pixels and the third pixels on the first virtual line, and the second metal layers may be arranged between the second pixels.

One of the first metal layers and one of the second metal layers that are disposed most adjacent to each other may be connected to each other and integral with each other.

The method may further include, after the removing of the spacer, forming an opposite electrode on the metal layer.

The pixel-defining layer may include an opening exposing at least a portion of an upper surface of each of the pixel electrodes, and the method may further include forming an emission layer overlapping the opening in a plan view.

The forming of the emission layer may be performed between the forming of the spacer and the removing of the spacer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to an embodiment;

FIG. 2A is a schematic diagram of an equivalent circuit of a pixel included in the display apparatus of FIG. 1 according to an embodiment;

FIG. 2B is a schematic diagram of an equivalent circuit of a pixel included in the display apparatus of FIG. 1 according to an embodiment;

FIG. 3 is a schematic plan view of a portion of a display area of the display apparatus of FIG. 1;

FIG. 4 is a schematic plan view of a portion of a display area of the display apparatus of FIG. 1;

FIG. 5 is a schematic plan view of a portion of a display area of the display apparatus of FIG. 1;

FIG. 6 is a schematic cross-sectional view of the display area, taken along a line I-I′ of FIG. 4; and

FIGS. 7A to 7H are schematic cross-sectional views sequentially showing a method of manufacturing a display apparatus according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

The X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

Sizes of elements in the drawings may be exaggerated or reduced for convenience of explanation. For example, the size and thickness of each element shown in the drawings are arbitrarily represented for convenience of description, and thus, the disclosure is not necessarily limited thereto.

In the case where a certain embodiment may be implemented differently, a specific process order may be performed in the order different from the described order. For example, two processes successively described may be simultaneously performed substantially and performed in the opposite order.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

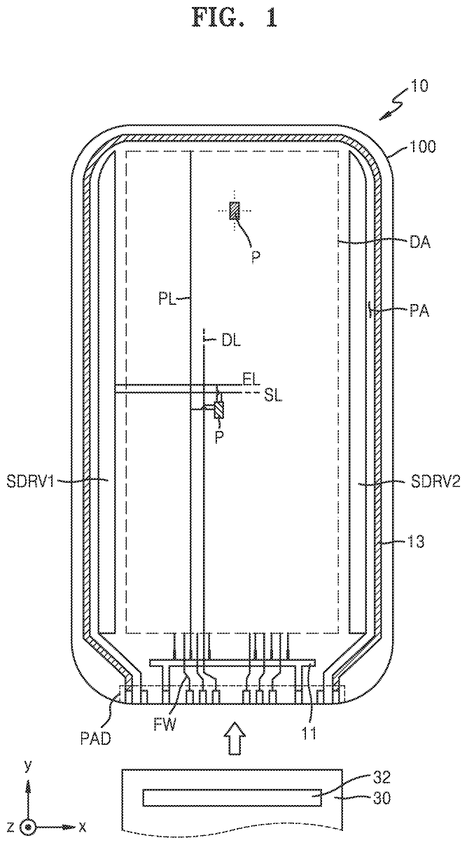

FIG. 1 is a schematic plan view of a display apparatus according to an embodiment.

FIG. 1 is a schematic plan view of a display panel 10 of the display apparatus according to an embodiment. As shown in FIG. 1, various elements included in the display panel 10 may be disposed on the substrate 100.

Multiple pixels P may be arranged in a display area DA. Each of the pixels P may include a display element such as an organic light-emitting diode OLED. Each pixel P may emit, for example, red, green, blue, or white light.

Pixel circuits that drive the display elements may each be electrically connected to outer circuits arranged in a peripheral area PA. A first scan driving circuit SDRV1, a second scan driving circuit SDRV2, a terminal part PAD, a driving voltage supply line 11, and a common voltage supply line 13 may be arranged in the peripheral area PA.

The first scan driving circuit SDRV1 may apply scan signals to a pixel circuit to drive the pixel P, through a scan line SL. The first scan driving circuit SDRV1 may also apply emission control signals to the pixel circuit, through an emission control line EL. The second scan driving circuit SDRV2 may be arranged opposite the first scan driving circuit SDRV1 with the display area DA disposed between the first scan driving circuit SDRV1 and the second scan driving circuit SDRV2, and may be approximately parallel to the first scan driving circuit SDRV1. Pixel circuits of some of the pixels P in the display area DA may be electrically connected to the first scan driving circuit SDRV1, and pixel circuits of another pixels P may be electrically connected to the second scan driving circuit SDRV2. In an embodiment, the second scan driving circuit SDRV2 may be omitted.

The terminal part PAD may be arranged on a side of the substrate 100. The terminal part PAD may be exposed and connected to a display circuit board 30 by not being covered by an insulating layer. A display driver 32 may be arranged on the display circuit board 30.

The display driver 32 may generate control signals and may send the control signals to the first scan driving circuit SDRV1 and the second scan driving circuit SDRV2. The display driver 32 may generate data signals, and the generated data signals may be transferred to the pixel circuits through fan-out wirings FW and the data lines DL connected to the fan-out wirings FW.

The display driver 32 may supply a driving voltage ELVDD (also referred to as a driving power voltage) to the driving voltage supply line 11 and supply a common voltage ELVSS (also referred to as an electrode power voltage) to the common voltage supply line 13. The driving voltage ELVDD may be applied to the pixel circuits of the pixels P, through a driving voltage line PL connected to the driving voltage supply line 11, and the common voltage ELVSS may be applied to an opposite electrode of the display element, through the common voltage supply line 13.

The driving voltage supply line 11 may be connected to the terminal part PAD and may extend in an x direction below the display area DA. The common voltage supply line 13 may be connected to the terminal part PAD, may have a loop shape having an open side, and partially surround the display area DA in a plan view.

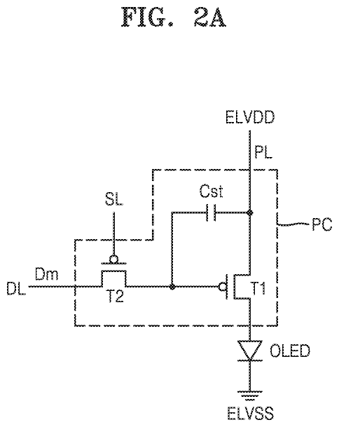

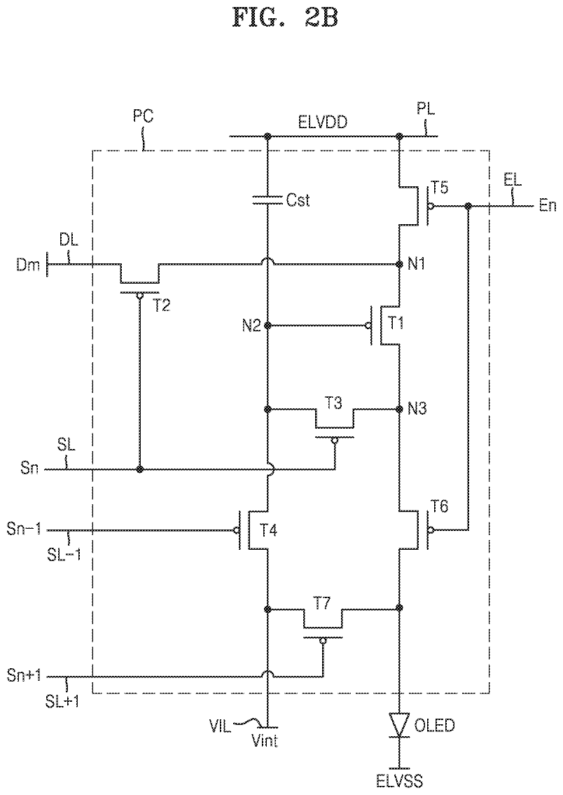

FIGS. 2A and 2B are schematic diagrams of an equivalent circuit of a pixel P included in the display apparatus of FIG. 1.

As shown in FIG. 2A, a pixel P may include a pixel circuit PC and an organic light-emitting diode OLED electrically connected to the pixel circuit PC.

The pixel circuit PC may include a first transistor T1, a second transistor T2, and a storage capacitor Cst. The second transistor T2 may be a switching thin-film transistor, may be connected to a scan line SL and a data line DL, may be turned on by a switching signal, and may transfer a data signal to the first transistor T1, the data signal being input from the data line DL, and the switching signal being input from the scan line SL. The storage capacitor Cst may include an end electrically connected to the second transistor T2, and another end electrically connected to a driving voltage line PL. The storage capacitor Cst may store a voltage corresponding to a difference between a voltage transferred from the second transistor T2 and the driving power voltage ELVDD supplied from the driving voltage line PL.

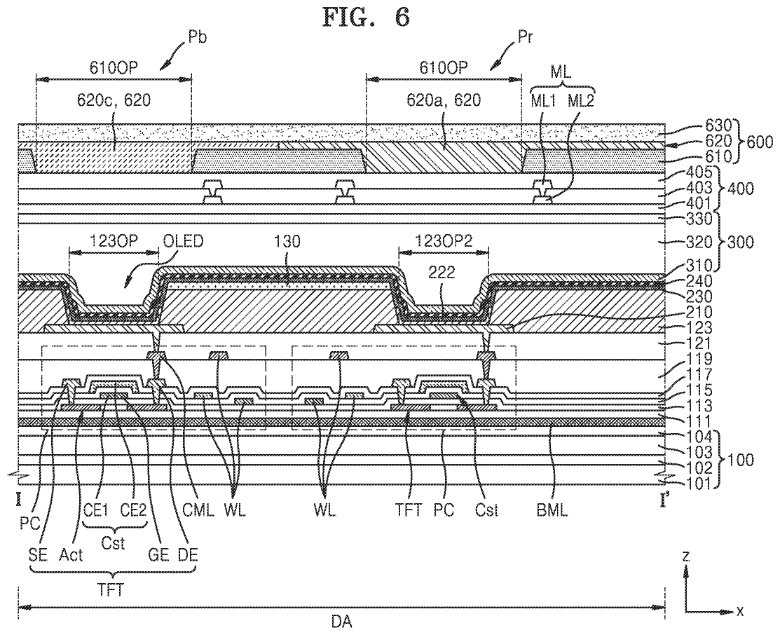

The first transistor T1 may be a driving transistor, may be connected to the driving voltage line PL and the storage capacitor Cst, and may control the magnitude of a driving current according to the voltage stored in the storage capacitor Cst, the driving current flowing from the driving voltage line PL to the organic light-emitting diode OLED. The organic light-emitting diode OLED may emit light having a brightness corresponding to the driving current. An opposite electrode 230 (see FIG. 6) of the organic light-emitting diode OLED may receive the electrode power voltage ELVSS.

Although it is described in FIG. 2A that the pixel circuit PC includes two transistors and one storage capacitor, the disclosure is not limited thereto. The number of transistors and the number of storage capacitors may be variously changed according to the design of the pixel circuit PC.

As shown in FIG. 2B, the pixel circuit PC may include first to seventh transistors T1, T2, T3, T4, T5, T6, and T7. Depending on the type (p-type or n-type) and/or an operation condition of a transistor, a first terminal of each of the first to seventh transistors T1, T2, T3, T4, T5, T6, and T7 may be one of a source terminal and a drain terminal, and a second terminal may be another one of the source terminal and the drain terminal. For example, in case that the first terminal is a source terminal, the second terminal may be a drain terminal.

The pixel circuit PC may be connected to a first scan line SL, a second scan line SL−1, a third scan line SL+1, the emission control line EL, the data line DL, the driving voltage line PL, and an initialization voltage line VL. The first scan line SL may transfer first scan signals Sn, the second scan line SL−1 may transfer second scan signals Sn−1, the third scan line SL+1 may transfer third scan signals Sn+1, the emission control line EL may transfer emission control signals En, the data line DL may transfer data signals Dm, the driving voltage line PL may transfer the driving power voltage ELVDD, and the initialization voltage line VL may transfer an initialization voltage Vint.

The first transistor T1 may be connected between the driving voltage line PL and the organic light-emitting diode OLED. The first transistor T1 may be connected to the driving voltage line PL through the fifth transistor T5, and electrically connected to the organic light-emitting diode OLED through the sixth transistor T6. The first transistor T1 may include a gate terminal, a first terminal, and a second terminal. The gate terminal may be connected to a second node N2, the first terminal may be connected to a first node N1, and the second terminal may be connected to a third node N3. The first transistor T1 may serve as a driving transistor, and may receive a data signal Dm and supply the driving current to a light-emitting element according to a switching operation of the second transistor T2.

The second transistor T2, which is a switching transistor, may be connected between the data line DL and the first node N1 and connected to the driving voltage line PL through the fifth transistor T5. The first node N1 may be a node to which the first transistor T1 and the fifth transistor T5 are connected. The second transistor T2 may include a gate terminal, a first terminal, and a second terminal. The gate terminal may be connected to the first scan line, the first terminal may be connected to the data line DL, and the second terminal may be connected to the first node N1 (or the first terminal of the first transistor T1). The second transistor T2 may be turned on according to a scan signal Sn transferred through the first scan line SL and may perform a switching operation of transferring a data signal Dm to the first node N1. The data signal Dm may be transferred through the data line DL.

The third transistor T3, which is a compensation transistor, may be connected between the second node N2 and the third node N3. The third transistor T3 may be connected to the organic light-emitting diode OLED through the sixth transistor T6. The second node N2 may be a node to which a gate electrode of the first transistor T1 is connected, and the third node N3 may be a node to which the first transistor T1 and the sixth transistor T6 are connected. The third transistor T3 may include a gate terminal, a first terminal, and a second terminal. The gate terminal may be connected to the first scan line SL, the first terminal may be connected to the second node N2 (or the gate terminal of the first transistor T1), and the second terminal may be connected to the third node N3 (or the second terminal of the first transistor T1). The third transistor T3 may be turned on according to a scan signal Sn to compensate for a threshold voltage of the first transistor T1 by diode-connecting the first transistor T1. The scan signal Sn may be transferred through the first scan line SL. The third transistor T3 may have a structure in which two or more transistors are connected in series.

The fourth transistor T4, which is a first initialization transistor, may be connected between the second node N2 and the initialization voltage line VL. The fourth transistor T4 may include a gate terminal, a first terminal, and a second terminal. The gate terminal may be connected to the second scan line SL−1, the first terminal may be connected to the second node N2, and the second terminal may be connected to the initialization voltage line VL. The fourth transistor T4 may be turned on according to a second scan signal Sn−1 to initialize the gate voltage of the first transistor T1 by transferring the initialization voltage Vint to the gate terminal of the first transistor T1. The second scan signal Sn−1 may be transferred through the second scan line SL−1.

The fifth transistor T5, which is an operation control transistor, may be connected between the driving voltage line PL and the first node N1. The sixth transistor T6, which is an emission control transistor, may be connected between the third node N3 and the organic light-emitting diode OLED. The fifth transistor T5 may include a gate terminal, a first terminal, and a second terminal. The gate terminal may be connected to the emission control line EL, the first terminal may be connected to the driving voltage line PL, and the second terminal may be connected to the first node N1. The sixth transistor T6 may include a gate terminal, a first terminal, and a second terminal. The gate terminal may be connected to the emission control line EL, the first terminal may be connected to the third node N3, and the second terminal may be connected to a pixel electrode of the organic light-emitting diode OLED. The fifth transistor T5 and the sixth transistor T6 may be simultaneously turned on according to an emission control signal En, and a current may flow through the organic light-emitting diode OLED. The emission control signal En may be transferred through the emission control line EL.

The seventh transistor T7, which is a second initialization transistor, may be connected between the organic light-emitting diode OLED and the initialization voltage line VL. The seventh transistor T7 may include a gate terminal, a first terminal, and a second terminal. The gate terminal may be connected to the third scan line SL+1, the first terminal may be connected to the second terminal of the sixth transistor T6 and the pixel electrode of the organic light-emitting diode OLED, and the second terminal may be connected to the initialization voltage line VL. The seventh transistor T7 may be turned on according to a third scan signal Sn+1 to initialize the voltage of the pixel electrode of the organic light-emitting diode OLED by transferring the initialization voltage Vint to the pixel electrode of the organic light-emitting diode OLED. The third scan signal Sn+1 may be transferred through the third scan line SL+1. In an embodiment, the seventh transistor T7 may be omitted.

The storage capacitor Cst may include a first electrode and a second electrode. The first electrode may be connected to the second node N2, and the second electrode may be connected to the driving voltage line PL. The storage capacitor Cst may maintain a voltage applied to the gate electrode of the first transistor T1 by storing and maintaining a voltage corresponding to a difference between voltages respectively supplied to two opposite ends of the first electrode and the second electrode. The first electrode of the storage capacitor Cst and the gate terminal of the first transistor T1 may be integral with each other.

The organic light-emitting diode OLED may include the pixel electrode and an opposite electrode facing the pixel electrode. The opposite electrode may receive the electrode power voltage ELVSS. The organic light-emitting diode OLED may display images by receiving the driving current from the first transistor T1 and emitting light of a preset color. The driving current may correspond to a voltage stored in the storage capacitor Cst. The opposite electrode may be provided in common, for example, as one body over the pixels.

Although it is shown in FIG. 2B that the transistors of the pixel circuit are P-type transistors, the disclosure is not limited thereto. For example, each of the transistors may be an N-type transistor, or some of the transistors may be P-type transistors and the rest may be N-type transistors. Various modifications may be made.

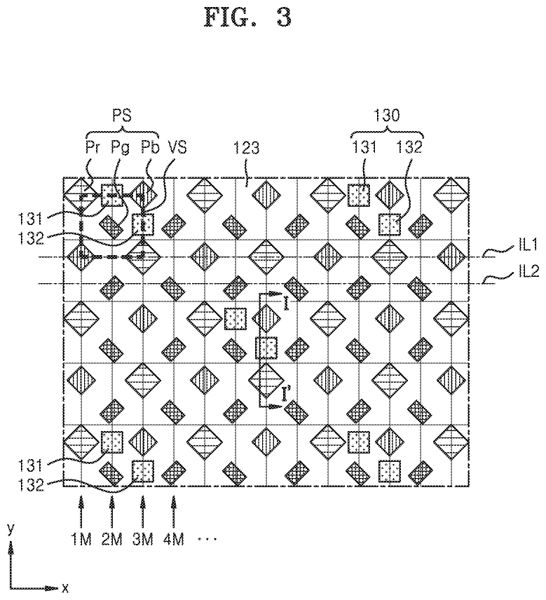

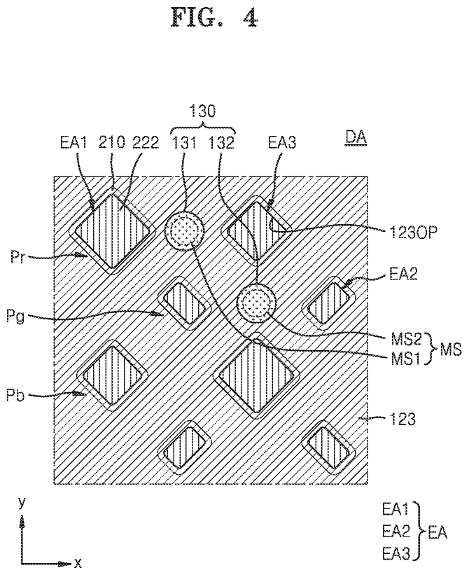

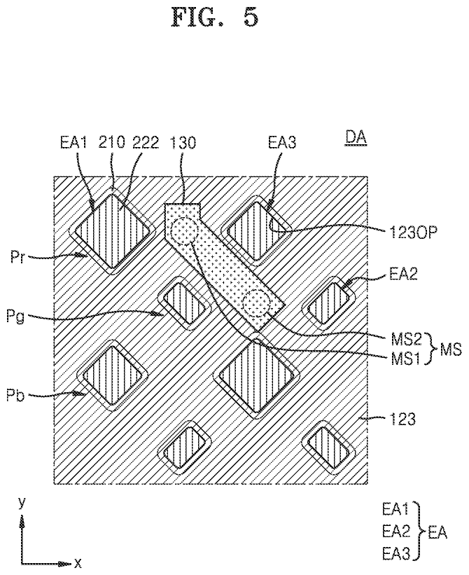

FIG. 3 is a schematic plan view of a portion of the display area DA of the display apparatus of FIG. 1, and FIGS. 4 and 5 are schematic enlarged plan views of a portion of the display area DA of the display apparatus of FIG. 3.

As shown in FIG. 3, pixel sets PS may be arranged in the display area DA, and the pixel sets PS may include first to third pixels that emit light of different colors. Hereinafter, for convenience of description, it will be described that the first pixel is a red pixel Pr, the second pixel is a green pixel Pg, and the third pixel is a blue pixel Pb. However, the disclosure is not limited thereto.

The red pixel Pr, the green pixel Pg, and the blue pixel Pb may be arranged in a pattern.

In an embodiment, the red pixel Pr, the green pixel Pg, and the blue pixel Pb may be alternately arranged in a first direction (an x axis direction). In an embodiment, the red pixel Pr and the blue pixel Pb may be alternately arranged along a first virtual line IL1 extending in the first direction (the x axis direction), and the green pixels Pg may be arranged along a second virtual line IL2 parallel and adjacent to the first virtual line IL1. The green pixels Pg may be arranged to correspond to a space between the red pixel Pr and the blue pixel Pb. The arrangement of the pixels in the first virtual line IL1 and the second virtual line IL2 may be repeated in a second direction (a y axis direction) intersecting the first direction (the x axis direction). The size (or the width) of each of the blue pixel Pb and the red pixel Pr may be greater than the size (or the width) of the green pixel Pg.

The red pixels Pr and the blue pixels Pb arranged along the first virtual line IL1, and the green pixels Pg arranged along the second virtual line IL2 may be alternately arranged. For example, the green pixels Pg may be arranged to correspond to a space between the red pixel Pr and the blue pixel Pb. Accordingly, the red pixel Pr and the blue pixel Pb may be alternately arranged in a first column 1m in the second direction (the y axis direction), the green pixels Pg may be arranged apart from each other at a preset interval in a second column 2M adjacent to the first column 1M, the blue pixel Pb and the red pixel Pr may be alternately arranged in a third column 3M adjacent to the second column 2M, and the green pixels Pg may be arranged apart from each other at a preset interval in a fourth column 4M adjacent thereto. The arrangement of the pixels in the first to fourth columns 1M, 2M, 3M, and 4M may be repeated in the first direction (the x axis direction).

For example, the pixels may be arranged as follows. Red pixels Pr may be disposed on first and third vertexes facing each other in a diagonal direction among the vertexes of a first virtual quadrangle VS with a green pixel Pg centered at the center of the quadrangle, and blue pixels Pb may be disposed on second and fourth vertexes, which are the rest of the vertexes of the first virtual quadrangle VS. The virtual quadrangle VS may be variously changed to a rectangle, a rhombus, a square, and the like. This pixel configuration structure may be referred to as a PenTile™. By applying rendering, in which color is represented by sharing adjacent pixels, a display apparatus of a high resolution may be implemented using a small number of pixels.

The pixel may be an emission area as a minimum unit that displays an image. In case that the organic light-emitting diode is used as a display element, the emission area of the pixel may be defined by an emission layer or an opening of a pixel-defining layer.

The red pixel Pr, the green pixel Pg, and the blue pixel Pb shown in FIG. 3 may respectively emit red light, green light, and blue light using light-emitting diodes. Accordingly, the configuration of the pixels may correspond to the configuration of light-emitting diodes, which are the display elements. For example, the position of the red pixel Pr shown in FIG. 3 may represent the position of the light-emitting diode that emits red light. Likewise, the position of the green pixel Pg may represent the position of the light-emitting diode that emits green light, and the position of the blue pixel Pb may represent the position of the light-emitting diode that emits blue light.

A display element of the red pixel Pr, a display element of the green pixel Pg, and a display element of the blue pixel Pb may be disposed on the upper portions of the relevant pixel circuits. The display element may be disposed on (e.g., directly on) the pixel circuit to overlap the pixel circuit in a plan view, or may be disposed to partially overlap the pixel circuit of another pixel that is offset from the pixel circuit and arranged in a row or column adjacent thereto. For example, the display element of the pixel may be arranged in a relevant pixel circuit region, or a portion of the display element may be arranged in another pixel circuit region adjacent to the relevant pixel circuit region.

A metal layer 130 may be disposed on a pixel-defining layer 123. The metal layer 130 may include multiple metal layers 130 spaced apart from each other. The metal layers 130 may be provided to correspond to spaces between the pixel electrodes 210. The metal layers 130 may be spaced apart from each other.

The metal layers 130 may be arranged with an interval. The metal layer 130 may be arranged with a regular interval in the first direction (the x axis direction). The metal layer 130 may be arranged at a regular interval in the second direction (the y axis direction).

The metal layers 130 may include first metal layers 131 and second metal layers 132. The first metal layers 131 may be arranged between the first pixel and the third pixel. Referring to FIG. 3, the first metal layers 131 may be arranged between the red pixel Pr and the blue pixel Pb that are alternately arranged in the first direction (the x direction). The second metal layers 132 may be arranged between the second pixels that are repeatedly arranged. Referring to FIG. 3, the second metals 132 may be arranged between the green pixels Pg repeated arranged in the first direction (the x direction).

The first metal layers 131 may be arranged with an interval. The second metal layers 132 may be arranged with an interval. The interval between the first metal layers 131 in a direction and the interval between the second metal layers 132 in the direction may be the same.

The metal layers 130 may have a same shape in a plan view. Although it is shown in FIG. 3 that the first metal layer 131 and the second metal layer 132 has a quadrangle with a same area in a plan view, the disclosure is not limited thereto. For example, the first metal layer 131 and the second metal layer 132 may have a polygon, a circular shape, an elliptical shape, or an irregular shape other than a quadrangular shape in a plan view.

As shown in FIG. 4, the first metal layer 131 and the second metal layer 132 may have a circular shape in a plan view. The first metal layer 131 and the second metal layer 132 may have different shapes and different areas in a plan view.

As shown in FIG. 5, the first metal layer 131 and the second metal layer 132 may be integral with each other, and the metal layer 130 may have a shape such as a polygon including a quadrangle, a circular shape, an elliptical shape, and an irregular shape in a plan view.

Referring to FIGS. 4 and 5, the pixel electrodes 210 of the red pixel Pr, the green pixel Pg, and the blue pixel Pb may be disposed on a planarization layer 121 (see FIG. 6) in the display area DA. The pixel-defining layer 123 may be arranged between the pixel electrodes 210, and the pixel-defining layer 123 may cover the edges of the pixel electrodes 210. The pixel-defining layer 123 may include through openings 123OP exposing a portion of the pixel electrodes 210. An emission layer 222 may be disposed on the pixel electrode 210 exposed by the through opening 123OP. An emission area EA corresponding to the emission layer 222 may be defined by a portion of the pixel electrode 210 exposed by the through opening 123OP of the pixel-defining layer 123.

The emission area EA may include a first emission area EA1, a second emission area EA2, and a third emission area EA3. The first emission area EA1 may correspond to the red pixel Pr, the second emission area EA2 may correspond to the green pixel Pg, and the third emission area EA3 may correspond to the blue pixel Pb.

The metal layer 130 may be arranged between the emission areas EA. The metal layer 130 may be arranged in a region other than the first emission area EA1, the second emission area EA2, and the third emission area EA3. A portion of the metal layer 130 may contact a portion of the edge of the first emission area EA1, the second emission area EA2, and the third emission area EA3.

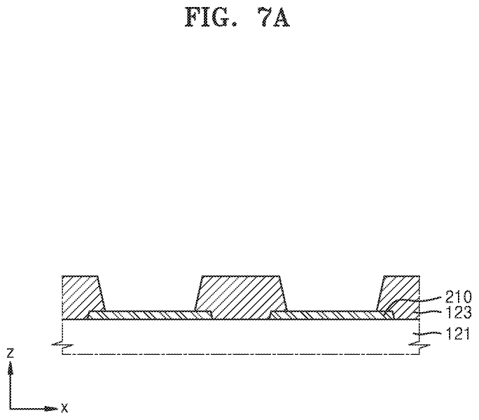

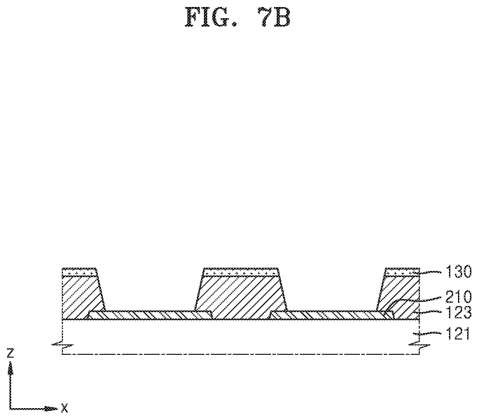

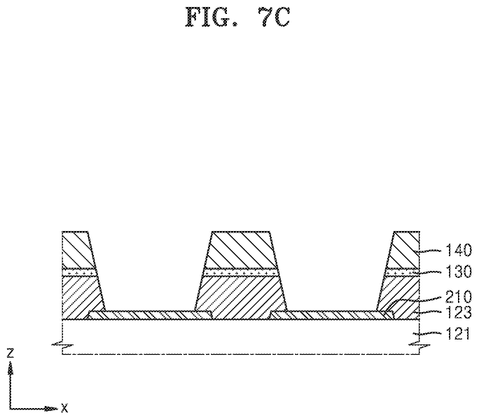

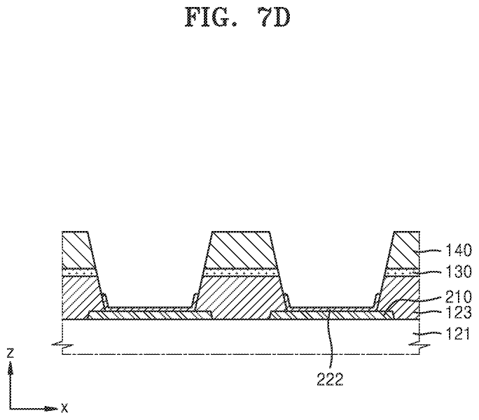

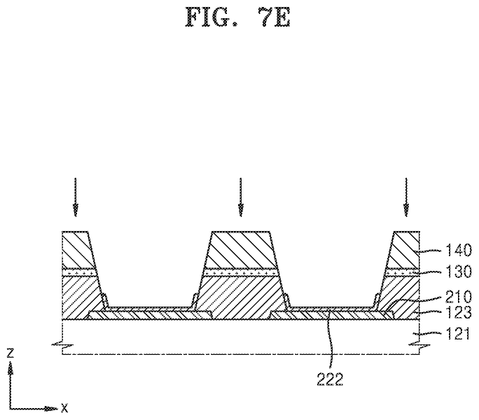

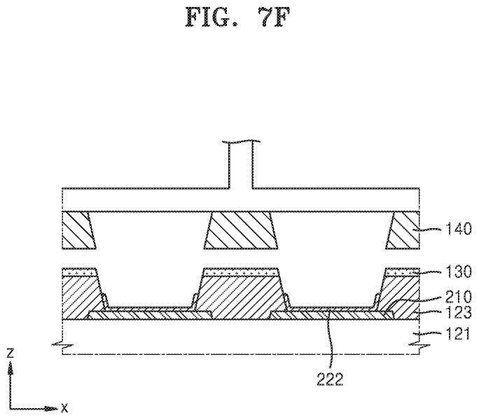

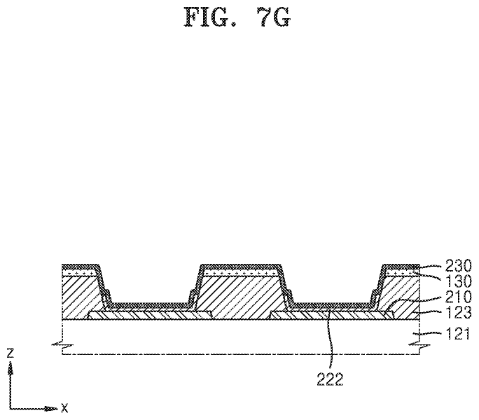

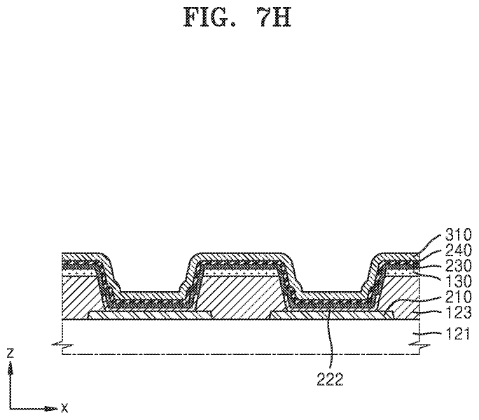

Referring to FIGS. 4 and 5, the metal layer 130 may overlap a spacer region MS. The spacer region MS may correspond to a region in which a spacer 140 (see FIG. 7C) is arranged. The spacer 140 may be used during the process of manufacturing the display apparatus and removed. The spacer region MS may include a first spacer region MS1 and a second spacer region MS2 spaced apart from the first spacer region MS1. The spacers 140 may be arranged in the first and second spacer regions MS1 and MS2 during the manufacturing process.

As shown in FIG. 4, the metal layer 130 may include the first metal layer 131 and the second metal layer 132. The first metal layer 131 may correspond to the first spacer region MS1, and the second metal layer 132 may correspond to the second spacer region MS2. In another embodiment, as shown in FIG. 5, a metal layer 130 may be provided, and the metal layer 130 may correspond to the first spacer region MS1 and the second spacer region MS2.

The spacer 140 may prevent the pixel-defining layer 123 from being damaged during a process of forming the emission layer 222. During forming of the pixel electrode 210 and the pixel-defining layer 123 and forming of the emission layer 222 and the like, with a fine metal mask (FMM) disposed on the pixel-defining layer 123, a material forming the emission layer 222 and the like may be deposited on the pixel electrode 210 through an opening of the fine metal mask (FMM). In case that the fine metal mask (FMM) contacts the pixel electrode 210 or the pixel-defining layer 123, the pixel electrode 210 or the pixel-defining layer 123 may be damaged, and thus, defects may occur. Because the spacer 140 contacts the fine metal mask (FMM) to support the fine metal mask (FMM) during the deposition process, the pixel electrode 210 or the pixel-defining layer 123 may be prevented from being damaged.

Accordingly, chopping due to the fine metal mask (FMM) may occur or impurities may remain on the upper surface of the spacer 140. Unevenness may be formed in the upper surface of the spacer 140 due to chopping or impurities present on the upper surface of the spacer 140. Due to this, a defective portion may occur to a layer formed on the spacer 140 during a subsequent process. For example, step coverage of an inorganic encapsulation layer covering the spacer 140 may be reduced and defects may occur. For performing successful deposition, the thickness of the inorganic encapsulation layer may need to be increased.

The display apparatus according to an embodiment may include the metal layer 130 on the pixel-defining layer 123. In case that chopping and the like occur on the upper surface of the spacer 140 during a process of forming the emission layer 222 using the spacer 140, the spacer 140 may be removed using the metal layer 130.

Because the metal layer 130 is disposed on the pixel-defining layer 123, unevenness may be prevented from occurring on the upper surface of the structure included in the display apparatus, and thus, the reliability of the display apparatus may be improved.

FIG. 6 is a schematic cross-sectional view of the display area, taken along line I-I′ of FIG. 5. FIG. 6 shows an embodiment that the light-emitting element, which is a display element, is an organic light-emitting diode.

Referring to FIG. 6, the organic light-emitting diode OLED may be disposed over the substrate 100.

The substrate 100 may include a first base layer 101, a first barrier layer 102, a second base layer 103, and a second barrier layer 104. The first base layer 101 and the second base layer 103 may each include a polymer resin, and the first barrier layer 102 and the second barrier layer 104 may each include an inorganic insulating material. The polymer resin may include polyethersulphone, polyacrylate, polyetherimide, polyethylene naphthalate, polyethylene terephthalate, polyphenylene sulfide, polyarylate, polyimide, polycarbonate, or cellulose acetate propionate. The inorganic insulating material may include silicon oxide, silicon nitride, or silicon oxynitride.

A buffer layer 111 may be disposed on the substrate 100. The buffer layer 111 may prevent or reduce penetration of foreign materials, moisture, or external air from the substrate 100. The buffer layer 111 may include an inorganic insulating material such as silicon oxide, silicon nitride, or silicon oxynitride, and may have a single-layered structure or a multi-layered structure including the above materials.

A bottom metal layer BML may be disposed between the substrate 100 and the buffer layer 111 and located in the display area DA and the peripheral area PA. The bottom metal layer BML may include a metal having conductivity such as aluminum (Al), platinum (Pt), palladium (Pd), silver (Ag), magnesium (Mg), gold (Au), nickel (Ni), neodymium (Nd), iridium (Ir), chromium (Cr), nickel (Ni), calcium (Ca), molybdenum (Mo), titanium (Ti), tungsten (W), copper (Cu), or a combination thereof. The bottom metal layer BML may be arranged to correspond to at least a portion of the pixel circuit PC. For example, the bottom metal layer BML may have a structure in which at least regions corresponding to driving transistors are connected to each other, and the bottom metal layer BML may include openings corresponding to the other circuit elements. In an embodiment, the bottom metal layer BML may be arranged in only the peripheral area PA or may be omitted in both the display area DA and the peripheral area PA.

The organic light-emitting diode OLED may be electrically connected to the pixel circuit PC corresponding thereto. The organic light-emitting diode OLED may be electrically connected to the pixel circuit PC disposed between the substrate 100 and the organic light-emitting diode OLED.

The pixel circuit PC may include a thin-film transistor TFT and a capacitor Cst. In an embodiment, the pixel circuit PC may include multiple wirings WL connected to the thin-film transistor TFT and the capacitor Cst. The thin-film transistor TFT may include a semiconductor layer Act, a gate electrode GE, a source electrode SE, and a drain electrode DE. The gate electrode GE may overlap a channel region of the semiconductor layer Act in a plan view, the source electrode SE may be connected to a source region of the semiconductor layer Act, and the drain electrode DE may be connected to a drain region of the semiconductor layer Act. The source electrode SE and the drain electrode DE may be portions of the wirings and may be defined as portions contacting the semiconductor layer Act. In case that the semiconductor layer Act of a thin-film transistor TFT is connected (e.g., directly connected) to a semiconductor layer Act of another thin-film transistor TFT, the another thin-film transistors may not include the source electrode SE and/or the drain electrode DE.

A first gate insulating layer 113 may be disposed between the semiconductor layer Act and the gate electrode GE, and a second gate insulating layer 115 and/or a first interlayer insulating layer 117 may be disposed between the gate electrode GE and the source electrode SE, and between the gate electrode GE and the drain electrode DE. A second interlayer insulating layer 119 may be disposed on the source electrode SE and the drain electrode DE.

The semiconductor layer Act may include polycrystalline silicon. In an embodiment, the semiconductor layer Act may include amorphous silicon. In an embodiment, the semiconductor layer Act may include an oxide semiconductor including at least one of indium (In), gallium (Ga), tin (Sn), zirconium (Zr), vanadium (V), hafnium (Hf), cadmium (Cd), germanium (Ge), chromium (Cr), titanium (Ti), and zinc (Zn). The semiconductor layer Act may include a channel region, a source region, and a drain region, the source region and the drain region being doped with an impurity.

The capacitor Cst may overlap the thin-film transistor TFT in a plan view. The capacitor Cst may include a lower electrode CE1 and an upper electrode CE2 overlapping each other in a plan view. In an embodiment, the gate electrode GE of the thin-film transistor TFT and the lower electrode CE1 of the capacitor Cst may be integral with each other.

The gate electrode GE or the lower electrode CE1 may include a conductive material of a low-resistance material such as molybdenum (Mo), aluminum (Al), copper (Cu) and/or titanium (Ti), and have a single-layered structure or a multi-layered structure including the above materials. For example, the gate electrode GE or the lower electrode CE1 may have a three-layered structure of Mo/Al/Mo.

The upper electrode CE2 may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), copper (Cu), or a combination thereof, and may have a single-layered structure or a multi-layered structure including the above materials. For example, the upper electrode CE2 may have a three-layered structure of Ti/Al/Ti. The second gate insulating layer 115 may be disposed between the lower electrode CE1 and the upper electrode CE2.

The source electrode SE and/or the drain electrode DE may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), copper (Cu), or a combination thereof, and may have a single-layered structure or a multi-layered structure including the above materials. For example, the source electrode SE and/or the drain electrode DE may have a three-layered structure of Ti/Al/Ti.

The first gate insulating layer 113, the second gate insulating layer 115, the first interlayer insulating layer 117, and the second interlayer insulating layer 119 may each include an inorganic insulating material such as silicon oxide, silicon nitride, or silicon oxynitride, and each have a single-layered structure or a multi-layered structure.

A planarization layer 121 may be disposed on the second interlayer insulating layer 119. The planarization layer 121 may include an organic material such as an acrylic material, benzocyclobutene (BCB), polyimide, hexamethyldisiloxane (HMDSO), or a combination thereof. In another embodiment, the planarization layer 121 may include an inorganic material. The planarization layer 121 may serve as a protective layer covering the first to seventh transistors T1, T2, T3, T4, T5, T6, and T7, and the upper surface of the planarization layer 121 may be flat. The planarization layer 121 may have a single-layered structure or a multi-layered structure.

The wirings WL may be disposed between the first gate insulating layer 113, the second gate insulating layer 115, the first interlayer insulating layer 117, the second interlayer insulating layer 119, and/or the planarization layer 121. The wirings WL may include a data line, a scan line, an emission control line, or the like connected to the thin-film transistors TFT and the capacitor Cst.

A connection electrode CML may be disposed on the second interlayer insulating layer 119. The thin-film transistor TFT may be electrically connected to the pixel electrode 210 of the organic light-emitting diode corresponding thereto through the connection electrode CML. The connection electrode CML may be connected to the thin-film transistor TFT through a contact hole of the second interlayer insulating layer 119, and the pixel electrode 210 may be connected to the connection electrode CML through a contact hole of the planarization layer 121.

The organic light-emitting diode OLED may have stacked structure of the pixel electrode 210, the emission layer 222, and the opposite electrode 230. The stacked structure may include a first functional layer (not shown) and/or a second functional layer (not shown). The first functional layer 221 may be disposed between the pixel electrode 210 and the emission layer 222, and the second functional layer may be disposed between the emission layer 222 and the opposite electrode 230.

The pixel electrode 210 may be disposed on the planarization layer 121. The pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. The pixel electrode 210 may include a reflective layer and a transparent conductive layer. The reflective layer may include the above materials, and the transparent conductive layer may be disposed on/under the reflective layer. The transparent conductive layer may include indium tin oxide (ITO), indium zinc oxide (IZO), zinc oxide (ZnO), indium oxide (In₂O₃), indium gallium oxide (IGO), aluminum zinc oxide (AZO), or a combination thereof. In an embodiment, the pixel electrode 210 may have a three-layered structure of ITO layer/Ag layer/ITO layer.

The pixel-defining layer 123 covering the edges of the pixel electrode 210 may include an opening overlapping the central portion of the pixel electrode 210 in a plan view. As shown in FIG. 6, the pixel-defining layer 123 may include a through opening 123OP overlapping the pixel electrode 210 of the organic light-emitting diode OLED in a plan view.

The through opening 123OP and a second through opening 123OP2 of the pixel-defining layer 123 may define an emission area of the organic light-emitting diode OLED and an emission area of a second organic light-emitting diode OLED. For example, the width of the through opening 123OP of the pixel-defining layer 123 may correspond to the width of the emission area of the organic light-emitting diode OLED.

The pixel-defining layer 123 may include a light-blocking insulating material. Accordingly, the pixel-defining layer 123 may be a colored opaque light-blocking insulating layer and may be, for example, black. For example, the pixel-defining layer 123 may include a polyimide (PI)-based binder and a pigment in which red, green, and blue are mixed. In another example, the pixel-defining layer 123 may include a cardo-based binder resin and a mixture of lactam black pigment and blue pigment. In another example, the pixel-defining layer 123 may include carbon black. The pixel-defining layer 123 may prevent reflection of external light in cooperation with an anti-reflection layer 600 and improve contrast of the display panel.

The emission layer 222 may be located to correspond to the through opening 123OP of the pixel-defining layer 123 and may overlap the pixel electrode 210 in a plan view. The emission layer 222 may include a polymer organic material or a low-molecular weight organic material that emits light having a color. The first functional layer and the second functional layer may be respectively formed under and on the emission layer 222.

The first functional layer may include a hole transport layer (HTL) and/or a hole injection layer (HIL). The second functional layer may include an electron transport layer (ETL) and/or an electron injection layer (EIL). Unlike the emission layer 222, the first functional layer and/or the second functional layer may be one body over the pixels. However, the disclosure is not limited thereto.

The metal layer 130 may be disposed on the pixel-defining layer 123. The metal layer 130 may cover the pixel-defining layer 123. The metal layer 130 may expose at least a portion of the upper surface of the pixel-defining layer 123. For example, as shown in FIG. 6, the metal layer 130 may be disposed on the pixel-defining layer 123 arranged between the blue pixel Pb and the red pixel Pr, but the metal layer 130 may be not disposed in another regions and expose the upper surface of the pixel-defining layer 123. The metal layer 130 may include aluminum (Al), titanium (Ti), silver (Ag), molybdenum (Mo), mendelevium (Mb), copper (Cu), or an alloy thereof.

The opposite electrode 230 may cover the metal layer 130. The opposite electrode 230 is disposed on (e.g., directly on) the metal layer 130 and may contact an entire area of the upper surface of the metal layer 130. The opposite electrode 230 may be disposed parallel to the upper surface of the substate 100. The opposite electrode 230 may be disposed side-by-side along the metal layer 130. The opposite electrode 230 disposed on the upper surface of the metal layer 130 may be disposed parallel to the upper surface of the metal layer 130.

A capping layer 240 may be disposed on the opposite electrode 230. The capping layer 240 may improve an external light-emission efficiency of the organic light-emitting diode OLED based on a constructive interference principle.

A thin-film encapsulation layer 300 may cover the organic light-emitting diode OLED. The thin-film encapsulation layer 300 may include a first inorganic encapsulation layer 310, a second inorganic encapsulation layer 330, and an organic encapsulation layer 320 disposed between the first inorganic encapsulation layer 310 and the second inorganic encapsulation layer 330.

Each of the first inorganic encapsulation layer 310 and the second inorganic encapsulation layer 330 may include at least one inorganic insulating material. For example, each of the first inorganic encapsulation layer 310 and the second inorganic encapsulation layer 330 may include aluminum oxide, titanium oxide, tantalum oxide, hafnium oxide, zinc oxide, silicon oxide, silicon nitride, silicon oxynitride, or a combination thereof.

The organic encapsulation layer 320 may include a polymer-based material. For example, the organic encapsulation layer 320 may include an acryl-based resin, an epoxy-based resin, polyimide, polyethylene, or a combination thereof. For example, the organic encapsulation layer 320 may include an acrylic resin including polymethyl methacrylate and/or polyacrylic acid. The organic encapsulation layer 320 may be formed by hardening a monomer or coating a polymer.

A touchscreen layer 400 may include a touch electrode, and the touch electrode may include a conductive layer ML. The touch electrode may include the conductive layer ML having a mesh structure surrounding the emission areas of the organic light-emitting diode OLED and the second organic light-emitting diode OLED2 in a plan view. As shown in FIG. 6, the conductive layer ML may have a connection structure of a first conductive layer ML1 and a second conductive layer ML2. In another embodiment, the conductive layer ML may include one of the first conductive layer ML1 and the second conductive layer ML2. The conductive layer ML may include at least one of molybdenum (Mo), mendelevium (Md), silver (Ag), titanium (Ti), copper (Cu), aluminum (Al), or an alloy thereof. An electrode, e.g., the conductive layer ML of the touchscreen layer 400, may be covered by the light-blocking layer 610.

The touchscreen layer 400 may include a first touch insulating layer 401, a second touch insulating layer 403, and a third touch insulating layer 405. The first touch insulating layer 401 may be disposed on the thin-film encapsulation layer 300, the second touch insulating layer 403 may be disposed on the first touch insulating layer 401, and the third touch insulating layer 405 may be disposed on the second touch insulating layer 403. The first conductive layer ML1 may be disposed between the first touch insulating layer 401 and the second insulating layer 403, and the second conductive layer ML2 may be disposed between the second touch insulating layer 403 and the third touch insulating layer 405.

The first touch insulating layer 401 to the third touch insulating layer 405 may include an inorganic insulating material and/or an organic insulating material. For example, the first touch insulating layer 401 and the second touch insulating layer 403 may include an inorganic insulating material, and the third touch insulating layer 405 may include an organic insulating material.

The light-blocking layer 610 of the anti-reflection layer 600 may include openings overlapping the emission area of the organic light-emitting diode OLED in a plan view. As shown in FIG. 6, the emission area of the organic light-emitting diode OLED and/or an opening 610OP may overlap the through opening 123OP of the pixel-defining layer 123 in a plan view.

The width of the opening 610OP of the light-blocking layer 610 may be equal to or greater than the width of the emission area of the organic light-emitting diode OLED and/or the through opening 123OP of the pixel-defining layer 123 in a direction (for example, in the first direction). As shown in FIG. 6, the width of the opening 610OP of the light-blocking layer 610 may be greater than the width of the emission area of the organic light-emitting diode OLED and/or the through opening 123OP of the pixel-defining layer 123.

A color filter 620 may be disposed in the opening 610OP of the light-blocking layer 610. As shown in FIG. 6, a first color filter 620a may be disposed in the opening 610OP of the red pixel Pr, and a third color filter 620c may be disposed in the opening 610OP of the blue pixel Pb. The color filter 620 may pass only light in a specific wavelength band corresponding to a wavelength of light emitted from the light-emitting diode disposed below the color filter 620. For example, as shown in FIG. 6, in case that one of the organic light-emitting diodes OLED in the display area DA emits red light, the color filter 620 disposed in the opening 610OP to overlap the organic light-emitting diode OLED may pass red light and not to pass most of green light or blue light.

An overcoat layer 630 may be disposed on the light-blocking layer 610 and the color filter 620. The overcoat layer 630 may be a light-transmissive layer and may planarize the upper surface of the light-blocking layer 610 and the upper surface of the color filter 620. The overcoat layer 630 may include a light-transmissive organic material such as an acryl-based resin.

FIGS. 7A to 7H are schematic cross-sectional views sequentially showing a method of manufacturing a display apparatus according to an embodiment.

A method of manufacturing a display apparatus according to an embodiment may include: forming the pixel electrodes 210 spaced apart from each other; forming the pixel-defining layer 123 covering the edges of each of the pixel electrodes 210; forming the metal layer 130 on the pixel-defining layer 123; and forming the spacer 140 on the metal layer.

First, referring to FIGS. 7A to 7C, the pixel electrodes 210 spaced apart from each other may be formed, and the pixel-defining layer 123 covering the edges of the pixel electrode may be formed. The metal layer 130 may be formed on the pixel-defining layer 123. The metal layer 130 may include multiple metal layers 130 spaced apart from each other. Although not shown in FIG. 7B, the metal layer 130 may expose at least a portion of the upper surface of the pixel-defining layer 123 as in FIGS. 3 to 5.

The spacer 140 may be formed on the upper surface of the metal layer 130. The spacer 140 and the pixel-defining layer 123 may include a same material. The spacer 140 may be formed in an area less than the area of the metal layer 130. In a plan view, the edge of the spacer 140 may be arranged inside the edge of the metal layer 130.

Referring to FIGS. 7D to 7F, the emission layer 222 may be formed. The emission layer 220 may be arranged to overlap the opening of the pixel-defining layer 123 in a plan view. The emission layer 222 may be formed using a fine metal mask including an opening arranged in a pattern. During this process, the spacer 140 may support the fine metal mask contacting the fine metal mask. Accordingly, unevenness due to chopping and impurities may be formed on the upper surface of the spacer 140.

The emission layer 222 may be formed, and the spacer 140 may be removed by irradiating a laser beam to the metal layer 130 disposed under the spacer 140. The spacer 140 may be removed by laser etching. In another embodiment, adhesive force between the lower portion of the metal layer 130 and the pixel-defining layer 123 may be reduced by irradiating a laser beam to the metal layer 130, and the spacer 140 may be removed by stamping. Accordingly, a structure deposited during a subsequent process may be formed on a very flat surface.

Referring to FIGS. 7G and 7F, the opposite electrode 230 may be formed on the metal layer 130 from which the spacer 140 is removed. The opposite electrode 230 may cover the upper surface of the metal layer 130 entirely. The opposite electrode 230 disposed on the upper surface of the metal layer 130 may be parallel to the upper surface of the metal layer 130. The capping layer 240 and the first inorganic encapsulation layer 310 may be disposed on the opposite electrode 230.

According to an embodiment having the above configuration, the display apparatus may have an improved reliability, wherein the metal layer is disposed on the pixel-defining layer, and the method of manufacturing the display apparatus may be implemented. However, the scope of the disclosure is not limited by this effect.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display apparatus comprising:
pixel electrodes disposed on a substrate, each of the pixel electrodes being spaced apart from each other;
a pixel-defining layer covering edges of each of the pixel electrodes;
metal layers disposed on the pixel-defining layer, having an island shape, disposed corresponding to spaces between the pixel electrodes, and spaced apart from each other; and
an opposite electrode covering the metal layers.

2. The display apparatus of claim 1, wherein the metal layers are arranged at constant interval.

3. The display apparatus of claim 1, wherein each of the metal layers have a same shape in a plan view.

4. The display apparatus of claim 1, further comprising:
first pixels, second pixels, and third pixels that emit light of different colors disposed on the substrate, wherein
the first pixels and the third pixels are alternately arranged along a first virtual line extending in a first direction,
the second pixels are arranged along a second virtual line parallel to the first virtual line and adjacent to the first virtual line corresponding to a space between adjacent ones of the first pixels and the third pixels,
the metal layers include first metal layers and second metal layers,
the first metal layers are arranged between adjacent ones of the first pixels and the third pixels on the first virtual line, and
the second metal layers are arranged between the second pixels.

5. The display apparatus of claim 4, wherein the first metal layers and the second metal layers are each arranged at constant interval in the first direction.

6. The display apparatus of claim 4, wherein an interval between the first metal layers and an interval between the second metal layers are same.

7. The display apparatus of claim 4, wherein one of the first metal layers and one of the second metal layers that are disposed most adjacent to each other are connected to each other and integral with each other.

8. The display apparatus of claim 1, wherein
the pixel-defining layer includes an opening exposing at least a portion of an upper surface of each of the pixel electrodes, and
the display apparatus further comprises an emission layer overlapping the opening in a plan view.

9. The display apparatus of claim 1, further comprising:
a capping layer and an inorganic encapsulation layer covering the opposite electrode.

10. A method of manufacturing a display apparatus, the method comprising:
preparing a substrate;
forming pixel electrodes spaced apart from each other on the substrate;
forming a pixel-defining layer covering edges of each of the pixel electrodes;
forming a metal layer on the pixel-defining layer;
forming a spacer on the metal layer; and
removing the spacer.

11. The method of claim 10, wherein the removing of the spacer includes irradiating a laser beam to the metal layer.

12. The method of claim 10, wherein the removing of the spacer includes performing a stamping process.

13. The method of claim 10, wherein
the metal layer includes a plurality of metal layers arranged in an island shape on the pixel-defining layer, and
the plurality of metal layers are spaced apart from each other.

14. The method of claim 13, wherein the plurality of metal layers have a same shape in a plan view.

15. The method of claim 13, wherein the plurality of metal layers are arranged at constant interval.

16. The method of claim 13, further comprising:
forming first pixels, second pixels, and third pixels that emit light of different colors on the substrate, wherein
the first pixels and the third pixels are alternately arranged along a first virtual line extending in a first direction,
the second pixels are arranged along a second virtual line parallel to the first virtual line and adjacent to the first virtual line corresponding to a space between adjacent ones of the first pixels and the third pixels,
the plurality of metal layers include first metal layers and second metal layers,
the first metal layers are arranged between adjacent ones of the first pixels and the third pixels on the first virtual line, and
the second metal layers are arranged between the second pixels.

17. The method of claim 16, wherein one of the first metal layers and one of the second metal layers that are disposed most adjacent to each other are connected to each other and integral with each other.

18. The method of claim 10, further comprising:
after the removing of the spacer, forming an opposite electrode on the metal layer.

19. The method of claim 10, wherein
the pixel-defining layer includes an opening exposing at least a portion of an upper surface of each of the pixel electrodes, and
the method further comprises forming an emission layer overlapping the opening in a plan view.

20. The method of claim 19, wherein the forming of the emission layer is performed between the forming of the spacer and the removing of the spacer.
